(19) United States
(12) Patent Application Publication
(10) Pub. No.: US 2013/0213433 A1
(43) Pub. Date: Aug. 22, 2013

(54) Method to Improve the Performance of a Leached Cutter

(71) Applicants: Federico Bellin, The Woodlands, TX (US); Vamsee Chintamaneni, Houston, TX (US)

(72) Inventors: Federico Bellin, The Woodlands, TX (US); Vamsee Chintamaneni, Houston, TX (US)

(73) Assignee: Varel International Ind., L.P., Carrollton, TX (US)

(21) Appl. No.: 13/401,452

(22) Filed: Feb. 21, 2012

(51) Int. Cl. B08B 3/12; B08B 3/08; B23B 27/20; G01R 27/26

(52) U.S. Cl. 134/1; 324/658; 134/93; 408/145

(57) ABSTRACT

A cleaned component having a polycrystalline structure, a method and apparatus for cleaning a leached component to form the cleaned component, and a method for determining the effectiveness of cleaning the leached component. The cleaned component includes a leached layer that has at least a portion of by-product materials removed. The by-product materials were deposited into the leached layer during a leaching process that formed the leached layer. The apparatus and method for cleaning includes a tank, a cleaning fluid placed within the tank, and at least a portion of the leached layer immersed into the cleaning fluid. Optionally, a transducer emits ultrasonic waves into the leached layer. The method for determining the effectiveness of cleaning includes cleaning the leached component to form the cleaned component, measuring one or more capacitance values of the cleaned component, repeating the cleaning and the measuring until achieving a stable lower limit capacitance value.

### RELATED APPLICATIONS

The present application is related to U.S. patent application Ser. No. 13/401,188, entitled “Use of Capacitance to Analyze Polycrystalline Diamond” and filed on Feb. 21, 2012, U.S. patent application Ser. No. 13/401,231, entitled “Use of Eddy Currents to Analyze Polycrystalline Diamond” and filed on Feb. 21, 2012, and U.S. patent application Ser. No. 13/401,335, entitled “Use of Capacitance and Eddy Currents to Analyze Polycrystalline Diamond” and filed on Feb. 21, 2012, which are all incorporated by reference herein.

### TECHNICAL FIELD

The present invention is directed generally to leached components having a polycrystalline structure; and more particularly, to a leached component having at least a portion of a leaching by-product material removed from a leached layer within the polycrystalline structure, a method for removing at least a portion of the by-product material from these leached components, and a method for testing the effectiveness of the method for removing.

### BACKGROUND

Polycrystalline diamond compacts (“PDC”) have been used in industrial applications, including rock drilling applications and metal machining applications. Such compacts have demonstrated advantages over some other types of cutting elements, such as better wear resistance and impact resistance. The PDC can be formed by sintering individual diamond particles together under the high pressure and high temperature (“HPHT”) conditions referred to as the “diamond stable region,” which is typically above forty kilobars and between 1,200 degrees Celsius and 2,000 degrees Celsius, in the presence of a catalyst/solvent which promotes diamond-diamond bonding. Some examples of catalyst/solvents for sintered diamond compacts are cobalt, nickel, iron, and other Group VIII metals. PDCs usually have a diamond content greater than seventy percent by volume, with about eighty percent to about ninety-eight percent being typical. An unbacked PDC can be mechanically bonded to a tool (not shown), according to one example. Alternatively, the PDC is bonded to a substrate, thereby forming a PDC cutter, which is typically insertable within, or mounted to, a downhole tool (not shown), such as a drill bit or a reamer.

FIG. 1 shows a side view of a PDC cutter 100 having a polycrystalline diamond (“PCD”) cutting table 110, or compact, in accordance with the prior art. Although a PCD cutting table 110 is described in the exemplary embodiment, other types of cutting tables, including polycrystalline boron nitride (“PCBN”) compacts, are used in alternative types of cutters. Referring to FIG. 1, the PDC cutter 100 typically includes the PCD cutting table 110 and a substrate 150 that is coupled to the PCD cutting table 110. The PCD cutting table 110 is about one hundred thousandths of an inch (2.5 millimeters) thick; however, the thickness is variable depending upon the application in which the PCD cutting table 110 is to be used.

The substrate 150 includes a top surface 152, a bottom surface 154, and a substrate outer wall 156 that extends from the circumference of the top surface 152 to the circumference of the bottom surface 154. The PCD cutting table 110 includes a cutting surface 112, an opposing surface 114, and a PCD cutting table outer wall 116 that extends from the circumference of the cutting surface 112 to the circumference of the opposing surface 114. The opposing surface 114 of the PCD cutting table 110 is coupled to the top surface 152 of the substrate 150. Typically, the PCD cutting table 110 is coupled to the substrate 150 using a high pressure and high temperature (“HPHT”) press. However, other methods known to people having ordinary skill in the art can be used to couple the PCD cutting table 110 to the substrate 150. In one embodiment, upon coupling the PCD cutting table 110 to the substrate 150, the cutting surface 112 of the PCD cutting table 110 is substantially parallel to the substrate's bottom surface 154. Additionally, the PDC cutter 100 has been illustrated as having a right circular cylindrical shape; however, the PDC cutter 100 is shaped into other geometric or non-geometric shapes in other exemplary embodiments. In certain exemplary embodiments, the opposing surface 114 and the top surface 152 are substantially planar; however, the opposing surface 114 and the top surface 152 is non-planar in other exemplary embodiments. Additionally, according to some exemplary embodiments, a bevel (not shown) is formed around at least a portion of the circumference of the cutting surface 112.

According to one example, the PDC cutter 100 is formed by independently forming the PCD cutting table 110 and the substrate 150, and thereafter bonding the PCD cutting table 110 to the substrate 150. Alternatively, the substrate 150 is initially formed and the PCD cutting table 110 is subsequently formed on the top surface 152 of the substrate 150 by placing polycrystalline diamond powder onto the top surface 152 and subjecting the polycrystalline diamond powder and the substrate 150 to a high temperature and high pressure process. Alternatively, the substrate 150 and the PCD cutting table 110 are formed and bonded together at about the same time. Although a few methods of forming the PDC cutter 100 have been briefly mentioned, other methods known to people having ordinary skill in the art can be used.

According to one example for forming the PDC cutter 100, the PCD cutting table 110 is formed and bonded to the substrate 150 by subjecting a layer of diamond powder and a mixture of tungsten carbide and cobalt powders to HPHT conditions. The cobalt is typically mixed with tungsten carbide and positioned where the substrate 150 is to be formed. The diamond powder is placed on top of the cobalt and tungsten carbide mixture and positioned where the PCD cutting table 110 is to be formed. The entire powder mixture is then subjected to HPHT conditions so that the cobalt melts and facilitates the cementing, or binding, of the tungsten carbide to form the substrate 150. The melted cobalt also diffuses, or infiltrates, into the diamond powder and acts as a catalyst for synthesizing diamond bonds and forming the PCD cutting table 110. Thus, the cobalt acts as both a binder for cementing the tungsten carbide and as a catalyst/solvent for sintering the diamond powder to form diamond-diamond bonds. The cobalt also facilitates in forming strong bonds between the PCD cutting table 110 and the cemented tungsten carbide substrate 150.

Cobalt has been a preferred constituent of the PDC manufacturing process. Traditional PDC manufacturing processes use cobalt as the binder material for forming the substrate 150 and also as the catalyst material for diamond synthesis because of the large body of knowledge related to using cobalt in these processes. The synergy between the large bodies of knowledge and the needs of the process have led to using cobalt as both the binder material and the catalyst material. However, as is known in the art, alternative metals, such as iron, nickel, chromium, manganese, and tantalum, and other suitable materials, can be used as a catalyst for diamond synthesis. When using these alternative materials as a catalyst for diamond synthesis to form the PCD cutting table 110, cobalt, or some other material such as nickel chrome or iron, is typically used as the binder material for cementing the tungsten carbide to form the substrate 150. Although some materials, such as tungsten carbide and cobalt, have been provided as examples, other materials known to people having ordinary skill in the art can be used to form the substrate 150, the PCD cutting table 110, and form bonds between the substrate 150 and the PCD cutting table 110.

FIG. 2 is a schematic microstructural view of the PCD cutting table 110 of FIG. 1 in accordance with the prior art. Referring to FIGS. 1 and 2, the PCD cutting table 110 has diamond particles 210 bonded to other diamond particles 210, one or more interstitial spaces 212 formed between the diamond particles 210, and cobalt 214 deposited within the interstitial spaces 212. During the sintering process, the interstitial spaces 212, or voids, are formed between the carbon-carbon bonds and are located between the diamond particles 210. The diffusion of cobalt 214 into the diamond powder results in cobalt 214 being deposited within these interstitial spaces 212 that are formed within the PCD cutting table 110 during the sintering process.

Once the PCD cutting table 110 is formed and placed into operation, the PCD cutting table 110 is known to wear quickly when the temperature reaches a critical temperature. This critical temperature is about 750 degrees Celsius and is reached when the PCD cutting table 110 is cutting rock formations or other known materials. The high rate of wear is believed to be caused by the differences in the thermal expansion rate between the diamond particles 210 and the cobalt 214 and also by the chemical reaction, or graphitization, that occurs between cobalt 214 and the diamond particles 210. The coefficient of thermal expansion for the diamond particles 210 is about 1.0×10⁻⁶ millimeters⁻¹×Kelvin⁻¹ (“mm⁻¹K⁻¹”), while the coefficient of thermal expansion for the cobalt 214 is about 13.0×10⁻⁶ mm⁻¹K⁻¹. Thus, the cobalt 214 expands much faster than the diamond particles 210 at temperatures above this critical temperature, thereby making the bonds between the diamond particles 210 unstable. The PCD cutting table 110 becomes thermally degraded at temperatures above about 750 degrees Celsius and its cutting efficiency deteriorates significantly.

Efforts have been made to slow the wear of the PCD cutting table 110 at these high temperatures. These efforts include performing conventional acid leaching processes of the PCD cutting table 110 which removes some of the cobalt 214 from the interstitial spaces 212. Conventional leaching processes involve the presence of an acid solution (not shown) which reacts with the cobalt 214, or other binder/catalyst material, that is deposited within the interstitial spaces 212 of the PCD cutting table 110. These acid solutions typically consist of highly concentrated solutions of hydrofluoric acid (HF), nitric acid (HNO₃), and/or sulfuric acid (H₂SO₄) and are subjected to different temperature and pressure conditions. These highly concentrated acid solutions are hazardous to individuals handling these solutions. According to one example of a conventional leaching process, the PDC cutter 100 is placed within an acid solution such that at least a portion of the PCD cutting table 110 is submerged within the acid solution. The acid solution reacts with the cobalt 214, or other binder/catalyst material, along the outer surfaces of the PCD cutting table 110. The acid solution slowly moves inwardly within the interior of the PCD cutting table 110 and continues to react with the cobalt 214. However, as the acid solution moves further inwards, the reaction byproducts become increasingly more difficult to remove; and hence, the rate of leaching slows down considerably within these conventional leaching processes. For this reason, a tradeoff occurs between conventional leaching process duration and the desired leaching depth, wherein costs increase as the conventional leaching process duration increases. Thus, the leaching depth is typically about 0.2 millimeters, which takes about days to achieve this depth. However, the leached depth can be more or less depending upon the PCD cutting table 110 requirements and/or the cost constraints. The removal of cobalt 214 alleviates the issues created due to the differences in the thermal expansion rate between the diamond particles 210 and the cobalt 214 and due to graphitization. Although it has been described that conventional leaching processes are used to remove at least some of the catalyst 214, other leaching processes or catalyst removal processes can be used to remove at least some of the catalyst 214 from the interstitial spaces 212.

FIG. 3 shows a cross-section view of a leached PDC cutter 300 having a PCD cutting table 310 that has been at least partially leached in accordance with the prior art. Referring to FIG. 3, the PDC cutter 300 includes the PCD cutting table 310 coupled to a substrate 350. The substrate 350 is similar to substrate 150 (FIG. 1) and is not described again for the sake of brevity. The PCD cutting table 310 is similar to the PCD cutting table 110 (FIG. 1), but includes a leached layer 354 and an unleached layer 356. The leached layer 354 extends from the cutting surface 312, which is similar to the cutting surface 112 (FIG. 1), towards an opposing surface 314, which is similar to the opposing surface 114 (FIG. 1). In the leached layer 354, at least a portion of the cobalt 214 has been removed from within the interstitial spaces 212 (FIG. 2) using at least one leaching process mentioned above. Thus, the leached layer 354 has been leached to a desired depth 353. However, as previously mentioned above, one or more by-product materials 398 are formed and deposited within some of the interstitial spaces 212 (FIG. 2) in the leached layer 354 during the leaching process. These by-product materials 398 are chemical by-products, or catalyst salts, of the dissolution reaction which are trapped within the open porosity of the interstitial spaces 212 (FIG. 2) after the dissolution process has been completed. The unleached layer 356 is similar to the PCD cutting table 150 (FIG. 1) and extends from the end of the leached layer 354 to the opposing surface 314. In the unleached layer 356, the cobalt 214 (FIG. 2) remains within the interstitial spaces 212 (FIG. 2). Although a boundary line 355 is formed between the leached layer 354 and the unleached layer 356 and is depicted as being substantially linear, the boundary line 355 can be non-linear.

The leached PDC cutters 300 are leached to different desired depths 353 and how deep the cutter 300 has been leached has an effect on the performance of the cutter 300. Further, the presence of by-product materials 398 within the leached layer 354 negatively impacts the performance of the leached PDC cutter 300.

### BRIEF DESCRIPTION OF THE DRAWINGS

The foregoing and other features and aspects of the invention are best understood with reference to the following description of certain exemplary embodiments, when read in conjunction with the accompanying drawings, wherein:

FIG. 1 shows a side view of a PDC cutter having a PCD cutting table in accordance with the prior art;

FIG. 2 is a schematic microstructural view of the PCD cutting table of FIG. 1 in accordance with the prior art;

FIG. 3 shows a cross-section view of a leached PDC cutter having a PCD cutting table that has been at least partially leached in accordance with the prior art;

FIG. 4 shows a cross-section view of a chemically cleaned leached PDC cutter having a PCD cutting table that has been at least partially leached and chemically cleaned in accordance with an exemplary embodiment;

FIG. 5 is a cross-sectional view of a by-products removal apparatus in accordance with an exemplary embodiment;

FIG. 6 is a cross-sectional view of a by-products removal apparatus in accordance with another exemplary embodiment;

FIG. 7 is a flowchart depicting a by-product materials removal verification method in accordance with an exemplary embodiment of the present invention;

FIG. 8 is a schematic view of a capacitance measuring system in accordance to one exemplary embodiment of the present invention;

FIG. 9 is a schematic view of a capacitance measuring system in accordance to another exemplary embodiment of the present invention;

FIG. 10 is a data scattering chart that shows the measured capacitance values for a plurality of leached and/or cleaned cutters at different cleaning cycles according to an exemplary embodiment;

FIG. 11 is a cross-sectional view of a by-products removal apparatus in accordance with another exemplary embodiment; and

FIG. 12 is a cross-sectional view of a by-products removal apparatus in accordance with another exemplary embodiment.

The drawings illustrate only exemplary embodiments of the invention and are therefore not to be considered limiting of its scope, as the invention may admit to other equally effective embodiments.

### BRIEF DESCRIPTION OF EXEMPLARY EMBODIMENTS

The present invention is directed generally to leached components having a polycrystalline structure; and more particularly, to a leached component having at least a portion of a leaching by-product material removed from a leached layer within the polycrystalline structure, a method for removing at least a portion of the by-product material from these leached components, and a method for testing the effectiveness of the method for removing. Although the description of exemplary embodiments is provided below in conjunction with a polycrystalline diamond compact (“PDC”) cutter, alternate embodiments of the invention may be applicable to other types of cutters or components including, but not limited to, polycrystalline boron nitride (“PCBN”) cutters or PCBN compacts. As previously mentioned, the compact is mountable to a substrate to form a cutter or is mountable directly to a tool for performing cutting processes. The invention is better understood by reading the following description of non-limiting, exemplary embodiments with reference to the attached drawings, wherein like parts of each of the figures are identified by like reference characters, and which are briefly described as follows.

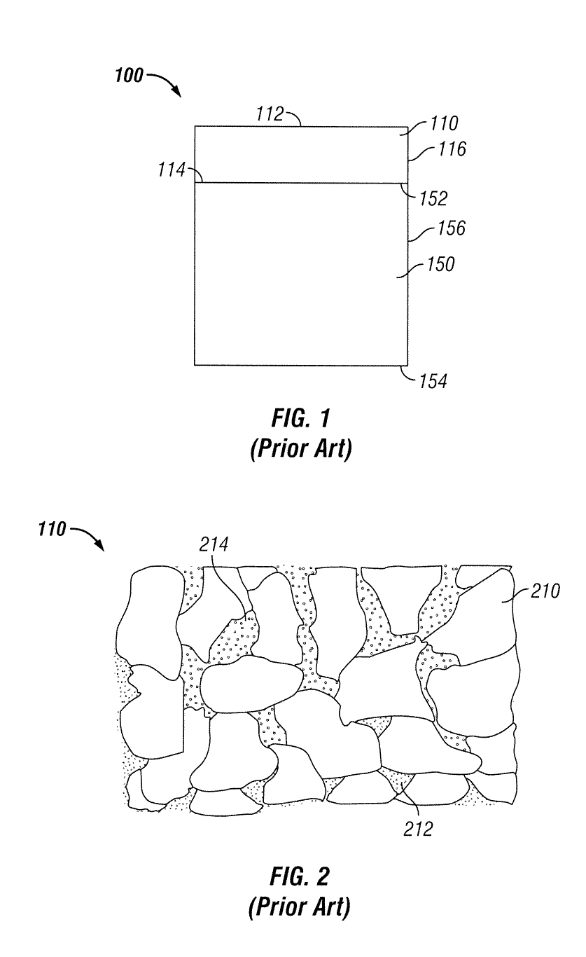

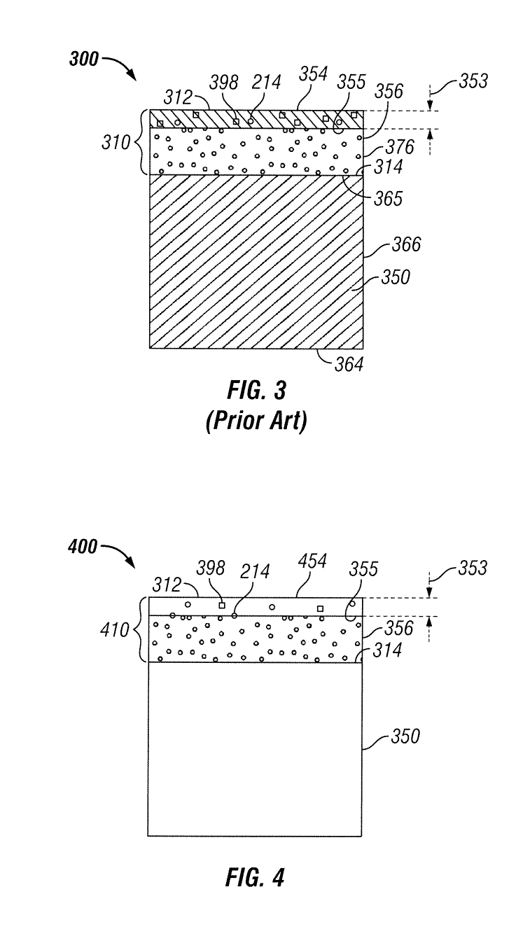

FIG. 4 shows a cross-section view of a chemically cleaned leached PDC cutter 400 having a PCD cutting table 410 that has been at least partially leached and chemically cleaned in accordance with an exemplary embodiment. Referring to FIG. 4, the chemically cleaned leached PDC cutter 400 includes the PCD cutting table 410 coupled to the substrate 350. The substrate 350 has been previously described above with respect to FIG. 3 and therefore is not described again for the sake of brevity. The PCD cutting table 410 is similar to the PCD cutting table 310 (FIG. 3), but has had at least a portion of the by-product materials 398 removed from a chemically cleaned leached layer 454. The chemically cleaned leached layer 454 is similar to leached layer 354 (FIG. 3) except that at least a portion of the by-product materials 398 is removed from the leached layer 354 (FIG. 3) to form the chemically cleaned leached layer 454. Thus, PCD cutting table 410 includes the chemically cleaned leached layer 454 and the unleached layer 356 which is disposed between the chemically cleaned leached layer 454 and the substrate 350. The chemically cleaned leached layer 454 extends from the cutting surface 312, which has been described above with respect to FIG. 3, towards the opposing surface 314, which also has been described with respect to FIG. 3. In the chemically cleaned leached layer 454, at least a portion of the cobalt 214 has been removed from within the interstitial spaces 212 (FIG. 2) using at least one leaching process mentioned above when compared to the PCD cutting table 110 (FIG. 1). Thus, the chemically cleaned leached layer 454 has been leached to the desired depth 353. However, as previously mentioned above, one or more by-product materials 398 were formed and deposited within some of the interstitial spaces 212 (FIG. 2) in the leached layer 354 (FIG. 3) during the leaching process. However, at least a portion of these by-product materials 398 are removed from the leached layer 354 (FIG. 3), thereby forming leached layer 454. The process of removing the by-product materials 398 from the leached layer 354 (FIG. 3) is described in further detail below. As previously mentioned, these by-product materials 398 are chemical by-products, or catalyst salts, of the dissolution reaction which are trapped within the open porosity of the interstitial spaces 212 (FIG. 2) after the dissolution process has been completed. The unleached layer 356 has been previously described with respect to FIG. 3 and therefore is not repeated for the sake of brevity. Although the boundary line 355 is formed between the chemically cleaned leached layer 454 and the unleached layer 356 and is depicted as being substantially linear, the boundary line 355 can be non-linear.

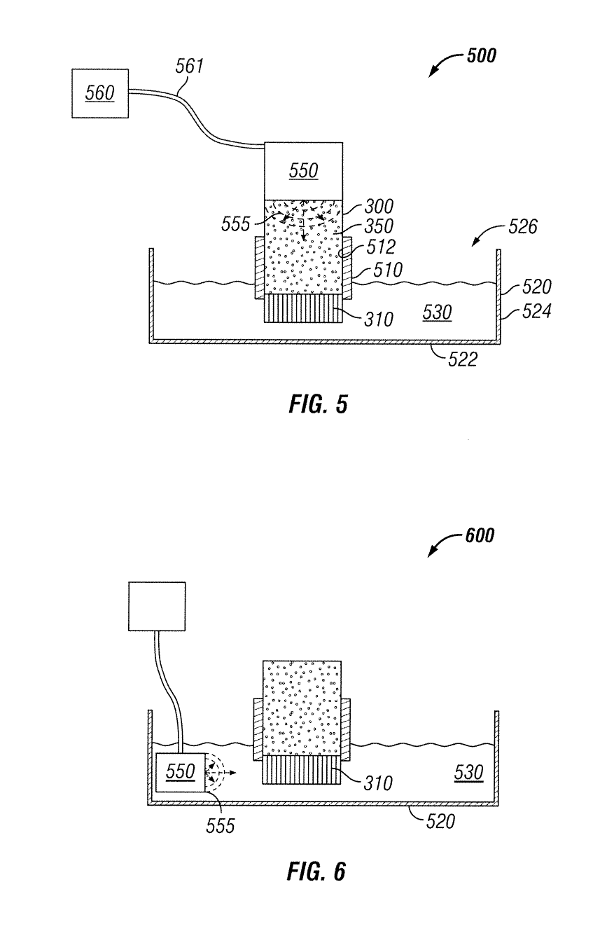

FIG. 5 is a cross-sectional view of a by-products removal apparatus 500 in accordance with an exemplary embodiment. Referring to FIG. 5, the by-products removal apparatus 500 includes the leached PDC cutter 300, a covering 510, an immersion tank 520, a cleaning fluid 530, a transducer 550, and at least one power source 560. According to certain exemplary embodiments, the covering 510 is optional. As the cleaning fluid 530 becomes increasingly more basic or more acidic, the use of the covering 510 becomes less optional.

The leached PDC cutter 300 has been previously described with respect to FIG. 3 and therefore is not described again in detail. Referring to FIGS. 3 and 5, the leached PDC cutter 300 includes the PCD cutting table 310 and the substrate 150 that is coupled to the PCD cutting table 310. As previously mentioned, the PCD cutting table 310 includes the leached layer 354 and the unleached layer 356 disposed between the leached layer 354 and the substrate 350. The leached layer 354 has at least a portion of the catalyst material 214 removed from therein using a known leaching process or some other process for removing the catalyst material 214. The leached layer 354 also includes by-product materials 398, which has been discussed in detail above and is not repeated again for the sake of brevity. The unleached layer 356 includes catalyst material 214. Although the PCD cutting table 310 is used in the exemplary embodiment, other types of cutting tables, including PCBN compacts, are used in alternative exemplary embodiments. The PCD cutting table 310 is about one hundred thousandths of an inch (2.5 millimeters) thick; however, the thickness is variable depending upon the application in which the PCD cutting table 310 is to be used.

Referring to FIGS. 3 and 5 and as previously mentioned, the by-products removal apparatus 500 includes the covering 510, which is optional. In certain exemplary embodiments, the covering 510 is annularly shaped and forms a channel 512 therein. The covering 510 surrounds at least a portion of a substrate outer wall 366 extending from about the perimeter of a top surface 365 of the substrate 350 towards a bottom surface 364 of the substrate 350. The bottom surface 364, the top surface 365, and the substrate outer wall 366 of substrate 350 are similar to the bottom surface 154 (FIG. 1), the top surface 152 (FIG. 1), and the substrate outer wall 156 (FIG. 1), respectively, of the substrate 150 (FIG. 1) and is not repeated herein again. In some exemplary embodiments, a portion of the covering 510 also surrounds a portion of the perimeter of a PCD cutting table outer wall 376 extending from the perimeter of the opposing surface 314 towards the cutting surface 312. The PCD cutting table outer wall 376 of the leached PDC cutter 300 is similar to the PCD cutting table outer wall 116 (FIG. 1) of the PDC cutter 100 (FIG. 1) and therefore is not repeated again. Thus, the cutting surface 312 and at least a portion of the PCD cutting table outer wall 376 is exposed and not concealed by the covering 510 in certain exemplary embodiments. The covering 510 is fabricated using epoxy resin; however, other suitable materials, such as a plastic, porcelain, or Teflon®, can be used without departing from the scope and spirit of the exemplary embodiment. In some exemplary embodiments, the covering 510 is positioned around at least a portion of the leached PDC cutter 300 by inserting the leached PDC cutter 300 through the channel 512 of the covering 510. The covering 510 is friction fitted to the leached PDC cutter 300 in some exemplary embodiments, while in other exemplary embodiments, the covering 510 is securely positioned by placing an o-ring (not shown), or other suitable known device, around the leached PDC cutter 300 and inserting the leached PDC cutter 300 and the coupled o-ring into the covering 510 so that the o-ring is inserted into a circumferential groove (not shown) formed within the internal surface of the covering 510. In an alternative exemplary embodiment, the covering 510 is circumferentially applied onto the substrate outer wall 366 and/or the PCD cutting table outer wall 376 of the leached PDC cutter 300. Although some methods for securing the covering 510 to the leached PDC cutter 300 have been described, other methods known to people having ordinary skill in the art can be used without departing from the scope and spirit of the exemplary embodiment. The covering 510 protects the surface of the substrate outer wall 366 and/or at least a portion of the PCD cutting table outer wall 376 to which it is applied from being exposed to the cleaning fluid 530, which is discussed in further detail below.

The immersion tank 520 includes a base 522 and a surrounding wall 524 extending substantially perpendicular around the perimeter of the base 522, thereby forming a cavity 526 therein. According to certain exemplary embodiments, the base 522 is substantially planar; however, the base 522 is non-planar in other exemplary embodiments. Also in alternative exemplary embodiments, the surrounding wall 524 is non-perpendicular to the base 522. Also, the immersion tank 520 is formed having a rectangular shape. Alternatively, the immersion tank 520 is formed having any other geometric shape or non-geometric shape. In some exemplary embodiments, the immersion tank 520 is fabricated using a plastic material; however, other suitable materials, such as metal, metal alloys, or glass, are used in other exemplary embodiments. The material used to fabricate the immersion tank 520 typically does not react with the cleaning fluid 530. According to some exemplary embodiments, a removable lid (not shown) is used to enclose at least the leached PDC cutter 300 and the transducer 550, thereby providing a seal to the cavity 530. Hence, the removable lid and the immersion tank 520 together form a pressurized vessel (not shown). In these exemplary embodiments, the power source 560 can be coupled to the lid, can be positioned outside the pressurized vessel as long as the pressurized vessel provides a port (not shown) to electrically couple the power source 560 to the transducer 550, or can be integrated with the transducer 550.

The cleaning fluid 530 is placed within the cavity 526 of the immersion tank 520 and filled to a depth of at least the thickness of the PCD cutting table 310. The cleaning fluid 530 is de-ionized water in the exemplary embodiment. The by-product materials 398 that clog the PCD open porosity is dissolvable in the cleaning fluid 530. According to some exemplary embodiments, one or more additional chemicals are added to the de-ionized water to form the cleaning fluid 530 and increase the rate at which the by-product materials 398 are dissolved into the cleaning fluid 530. These additional chemicals are based upon the composition of the by-product materials 398. Some examples of these additional chemicals are acetic acid and/or formic acid to make the solution slightly acidic or ammonia to make the solution slightly basic. However, in other exemplary embodiments, any fluid or solution that is able to dissolve and/or react with the by-product materials 398 can be used for the cleaning fluid 530 in lieu of, or in addition to, the de-ionized water. According to some exemplary embodiments, the cleaning fluid 530 is heated to increase the rate at which the by-product materials 398 are dissolved into the cleaning fluid 530 and hence accelerate the cleaning process. The temperature of the cleaning fluid 530 can be heated up to 100° C. in the immersion tank 520 or some similar type tank. However, the temperature of the cleaning fluid 530 can be heated higher than 100° C. in the pressurized vessel mentioned above, thereby avoiding or reducing boiling of the cleaning fluid 530.

The transducer 550 is coupled to the leached PDC cutter 300 according to some exemplary embodiments. According to some exemplary embodiments, a portion of the transducer 550 is coupled to the bottom surface 364 of the leached PDC cutter 300; however the transducer 550 can be coupled to a portion of the substrate outer wall 366 in other exemplary embodiments. Alternatively, the transducer 550 is coupled to a portion of the immersion tank 520 or positioned within the cleaning fluid 530, thereby producing vibrations which propagate through the cleaning fluid 530 and into the leached PDC cutter 300. The transducer 550 also is coupled to a power source 560 using an electrical wire 561. The transducer 550 converts electric current supplied from the power source 560 into vibrations that are propagated through the leached PDC cutter 300. The transducer 550 is shaped into a cylindrical shape and has a circumference sized approximately similarly to the circumference of the bottom surface 364. However, the shape and size of the transducer 550 varies in other exemplary embodiments. The transducer 550 is a piezoelectric transducer; however, the transducer 550 is a magnetostrictive transducer in other exemplary embodiments. The transducer 550 operates at a frequency of about 40 kilohertz (kHz) in some exemplary embodiments. In other exemplary embodiments, the transducer 550 operates at a frequency ranging from about 20 kHz to about 50 kHz; yet, in still other exemplary embodiments, the operating frequency is higher or lower than the provided range. The transducer 550 supplies ultrasonic vibrations 555 which propagate through the leached PDC cutter 300 and facilitate the by-product materials 398 removal from the interstitial spaces 212 (FIG. 2) formed within the PCD cutting table 310, which is further described below.

Once the by-products removal apparatus 500 has been set up and at least a portion of the PCD cutting table 310 is immersed into the cleaning fluid 530, the cleaning fluid 530 penetrates into the leached layer 354 and dissolves the by-product materials 398 that are clogging the PCD open porosity. The by-product materials 398 are highly soluble in the cleaning fluid 530. In certain exemplary embodiments, the transducer 550 and the power source 560 are included in the by-product removal apparatus 500. The power source 560 is turned “on” to facilitate removal of the by-product materials 398 from the PCD cutting table 310 back into the cleaning fluid 530. The transducer 550 produces ultrasonic vibrations 555 into the leached PDC cutter 300 which promotes the removal of the by-product materials 398 from the PCD cutting table 310 back into the cleaning fluid 530. The operating frequency of the transducer 550 and the intensity of the elastic waves emitted from the transducer can be adjusted to maximize the amount of vibrations 555 delivered to the PCD cutting table 310. Furthermore, the ultrasonic vibrations 555 mechanically improve the cleaning fluid 530 circulation rate into and out of the interstitial spaces 212 (FIG. 2), thereby providing fresh cleaning fluid 530 into the interstitial spaces 212 (FIG. 2). Once the by-product material 398 is removed from the PCD cutting table 310, the cleaning fluid 530 is able to proceed deeper into the PCD cutting table 310 and dissolve more by-product materials 398 located within additional interstitial voids 212 (FIG. 2). Upon at least some of the by-product materials 398 being removed from the leached layer 354, the leached PDC cutter 300 becomes the chemically cleaned leached PDC cutter 400 (FIG. 4). Although a single leached PDC cutter 300 is shown to be immersed in the cleaning fluid 530, several leached PDC cutters 300 can be immersed into the cleaning fluid 530 to remove the by-product materials 398 from the PCD cutting table 310 simultaneously in other exemplary embodiments.

FIG. 6 is a cross-sectional view of a by-products removal apparatus 600 in accordance with another exemplary embodiment. The by-products removal apparatus 600 is similar to the by-products removal apparatus 500 (FIG. 5) except that the transducer 550 of the by-products removal apparatus 600 is submerged within the cleaning fluid 530. The transducer 550 transmits ultrasonic vibrations 555 into the cleaning fluid 530, which then transmits the vibrations 555 into the PCD cutting table 310. As previously mentioned, the ultrasonic vibrations 555 facilitate removal of the by-product materials 398, or salt, within the interstitial void 212 (FIG. 2) and increase the recirculation rate of the fresh cleaning fluid 530 into the PCD cutting table 310. Thus, the by-product material 398 removal rate is substantially increased. Alternatively, the transducer 550 is coupled to a portion of the immersion tank 520. The other exemplary embodiments and/or modifications as described with respect to FIG. 5 above are applicable to the present exemplary embodiment.

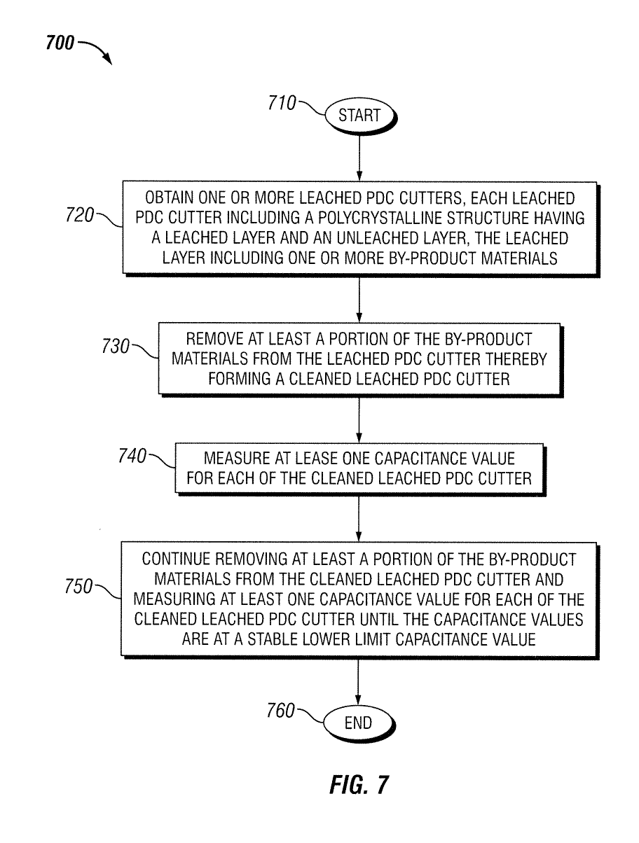

FIG. 7 is a flowchart depicting a by-product materials removal verification method 700 in accordance with an exemplary embodiment of the present invention. Although FIG. 7 shows a series of steps depicted in a certain order, the order of one or more steps can be rearranged, combined into fewer steps, and/or separated into more steps than that shown in other exemplary embodiments. Referring to FIG. 7, the by-product materials removal verification method 700 begins at step 710. Upon starting at step 710, the by-product materials removal verification method 700 proceeds to step 720. At step 720, one or more leached PDC cutters are obtained. According to certain exemplary embodiments, each leached PDC cutter includes a polycrystalline structure having a leached layer and an unleached layer. The leached layer includes one or more by-product materials. These leached PDC cutters have been described above in detail with respect to FIG. 3 and therefore is not described again for the sake of brevity.

The by-product materials removal verification method 700 proceeds to step 730. At step 730, at least a portion of the by-product materials from the leached PDC cutter is removed thereby forming a cleaned leached PDC cutter. The by-product materials are removed from the leached PDC cutter using the by-products removal apparatus 500 (FIG. 5), the by-products removal apparatus 600 (FIG. 6), or some other by-products removal apparatus that becomes known to other people having ordinary skill in the art with the benefit of the present disclosure. As previously described, a cleaning fluid and a transducer, according to some exemplary embodiments, are used to remove at least a portion of the by-product materials from the leached PDC cutter.

The by-product materials removal verification method 700 proceeds to step 740. At step 740, at least one capacitance value for each of the cleaned leached PDC cutter is measured. The cleaned leached PDC cutter has been described above in detail with respect to FIG. 4 and therefore is not described again for the sake of brevity. The capacitance value is determined using a capacitance measuring system, as described below.

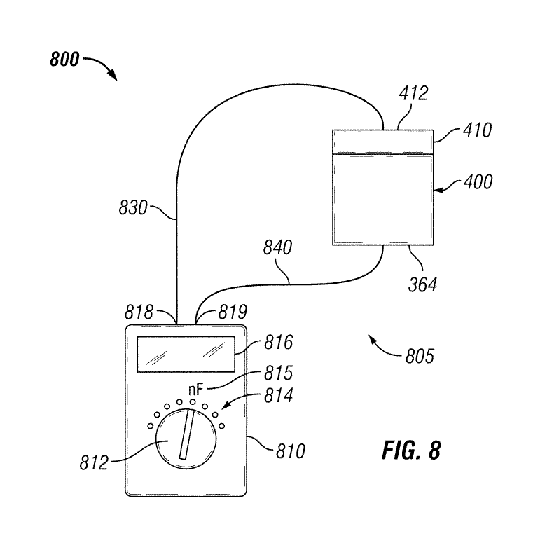

FIG. 8 is a schematic view of a capacitance measuring system 800 in accordance to one exemplary embodiment of the present invention. Referring to FIG. 8, the capacitance measuring system 800 includes a capacitance measuring device 810, the cleaned leached PDC cutter 400, a first wire 830, and a second wire 840. In other exemplary embodiments, the leached PDC cutter 300 (FIG. 3) is used in lieu of the cleaned leached PDC cutter 400. Although certain components have been enumerated as being included in the capacitance measuring system 800, additional components are included in other exemplary embodiments. Additionally, although the description provided below has been provided with respect to the cleaned leached PDC cutter 400, a different component, such as the PCD cutting table 410 alone or other component that includes another type of clean leached polycrystalline structure or leached polycrystalline structure, is used in lieu of the cleaned leached PDC cutter 400. The cleaned leached PDC cutter 400 has been previously described with respect to FIG. 4 and is not repeated again herein for the sake of brevity.

The capacitance measuring device 810 is a device that measures the capacitance of an energy storage device, which is the cleaned leached PDC cutter 400, or the leached PDC cutter 300 (FIG. 3), in the instant exemplary embodiment. Capacitance is a measure of the amount of electric potential energy stored, or separated, for a given electric potential. A common form of energy storage device is a parallel-plate capacitor. In the instant exemplary embodiment, the cleaned leached PDC cutter 400 is an example of the parallel-plate capacitor. The capacitance of the energy storage device is typically measured in farads, or nanofarads.

One example of the capacitance measuring device 810 is a multi-meter; however, other capacitance measuring devices known to people having ordinary skill in the art are used in one or more alternative exemplary embodiments. The multi-meter 810 includes a positionable dial 812, a plurality of measurement settings 814, a display 816, a positive terminal 818, and a negative terminal 819. According to some exemplary embodiments, the positionable dial 812 is rotatable in a clockwise and/or counter-clockwise manner and is set to one of several available measurement settings 814. In the instant exemplary embodiment, the positionable dial 812 is set to a nanofaraday setting 815 so that the multi-meter 810 measures capacitance values. The display 816 is fabricated using polycarbonate, glass, plastic, or other known suitable material and communicates a measurement value, such as a capacitance value, to a user (not shown) of the multi-meter 810. The positive terminal 818 is electrically coupled to one end of the first wire 830, while the negative terminal 819 is electrically coupled to one end of the second wire 840.

The first wire 830 is fabricated using a copper wire or some other suitable conducting material or alloy known to people having ordinary skill in the art. According to some exemplary embodiments, the first wire 830 also includes a non-conducting sheath (not shown) that surrounds the copper wire and extends from about one end of the copper wire to an opposing end of the cooper wire. The two ends of the copper wire are exposed and are not surrounded by the non-conducting sheath. In some exemplary embodiments, an insulating material (not shown) also surrounds the copper wire and is disposed between the copper wire and the non-conducting sheath. The insulating material extends from about one end of the non-conducting sheath to about an opposing end of the non-conducting sheath. As previously mentioned, one end of the first wire 830 is electrically coupled to the positive terminal 818, while the opposing end of the first wire 830 is electrically coupled to the cutting surface 812 of the cleaned leached PDC cutter 400. The opposing end of the first wire 830 is electrically coupled to the cutting surface 412 in one of several methods. In one example, the first wire 830 is electrically coupled to the cutting surface 412 using one or more fastening devices (not shown), such as a clamp, or using an equipment (not shown) that supplies a force to retain the first wire 830 in electrical contact with the cutting surface 412. In another example, a clamp (not shown) is coupled to the opposing end of the first wire 830 and a conducting component (not shown), such as aluminum foil, is coupled to, or placed in contact with, the cutting surface 412. The clamp is electrically coupled to the conducting component, thereby electrically coupling the first wire 830 to the cutting surface 412. Additional methods for coupling the first wire 830 to the cutting surface 412 can be used in other exemplary embodiments.

The second wire 840 is fabricated using a copper wire or some other suitable conducting material or alloy known to people having ordinary skill in the art. According to some exemplary embodiments, the second wire 840 also includes a non-conducting sheath (not shown) that surrounds the copper wire and extends from about one end of the copper wire to an opposing end of the cooper wire. The two ends of the copper wire are exposed and are not surrounded by the non-conducting sheath. In some exemplary embodiments, an insulating material (not shown) also surrounds the copper wire and is disposed between the copper wire and the non-conducting sheath. The insulating material extends from about one end of the non-conducting sheath to an opposing end of the non-conducting sheath. As previously mentioned, one end of the second wire 840 is electrically coupled to the negative terminal 819, while the opposing end of the second wire 8440 is electrically coupled to a bottom surface 364, which is similar to the bottom surface 154 (FIG. 1), of the cleaned leached PDC cutter 400. The second wire 840 is electrically coupled to the bottom surface 364 in a similar manner as the first wire 830 is electrically coupled to the cutting surface 412.

Hence, a circuit 805 is completed using the multi-meter 810, the first wire 830, the cleaned leached PDC cutter 400, and the second wire 840. The current is able to flow from the positive terminal 818 of the multi-meter 810 to the cutting surface 412 of the cleaned leached PDC cutter 400 through the first wire 830. The current then flows through the cleaned leached PDC cutter 400 to the bottom surface 364 of the cleaned leached PDC cutter 400. When the multi-meter 810 is turned on, a voltage differential exists between the cutting surface 412 and the bottom surface 364. The current then flows from the bottom surface 3644 to the negative terminal 819 of the multi-meter 810 through the second wire 840. The capacitance measurement of the cleaned leached PDC cutter 400 is determined when the value displayed on the display 816 reaches a peak value or remains constant for a period of time. The use, analyzing of the results, and other information regarding the capacitance measuring system 800 is described in U.S. patent application Ser. No. 13/401,188, entitled “Use of Capacitance to Analyze Polycrystalline Diamond” and filed on Feb. 21, 2012, which has been incorporated by reference herein.

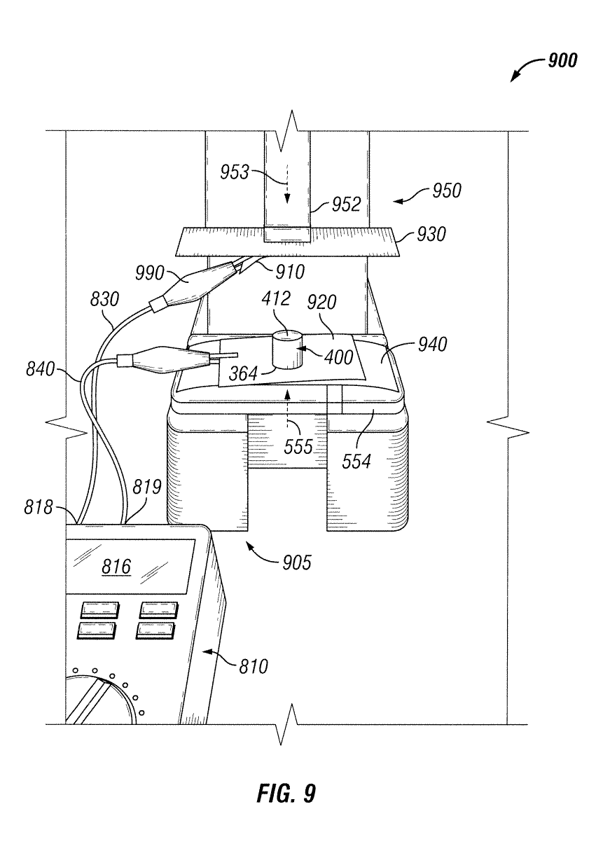

FIG. 9 is a schematic view of a capacitance measuring system 900 in accordance to another exemplary embodiment of the present invention. Referring to FIG. 9, the capacitance measuring system 900 includes the capacitance measuring device 810, the cleaned leached PDC cutter 400, the first wire 830, the second wire 840, a first conducting material 910, a second conducting material 520, a first insulating material 930, a second insulating material 940, and an Arbor Press 950. In certain alternative exemplary embodiments, the leached PDC cutter 300 (FIG. 3) is used in lieu of the cleaned leached PDC cutter 400. Although certain components have been enumerated as being included in the capacitance measuring system 900, additional components are included in other exemplary embodiments. Further, although certain components have been enumerated as being included in the capacitance measuring system 900, alternative components having similar functions as the enumerated components are used in alternative exemplary embodiments. Additionally, although the description provided below has been provided with respect to the cleaned leached PDC cutter 400, a different component, such as the PCD cutting table 410 (FIG. 4) alone or other component that includes another type of leached, or cleaned leached, polycrystalline structure, is used in lieu of the cleaned leached PDC cutter 400. The capacitance measuring device 810, the cleaned leached PDC cutter 400, the first wire 830, and the second wire 840 have been previously described and are not repeated again herein for the sake of brevity.

The first conducting material 910 and the second conducting material 920 are similar to one another in certain exemplary embodiments, but are different in other exemplary embodiments. According to one exemplary embodiment, the conducting materials 910, 920 are fabricated using aluminum foil; however, other suitable conducting materials can be used. The first conducting material 910 is positioned adjacently above and in contact with the cutting surface 412. The second conducting material 920 is positioned adjacently below and in contact with the bottom surface 364. The first conducting material 910 and the second conducting material 920 provide an area to which the first wire 830 and the second wire 840, respectively, make electrical contact. Additionally, the first conducting material 910 and the second conducting material 920 assist in minimizing contact resistance with the cutting surface 412 and the bottom surface 364, respectively, which is discussed in further detail below. In certain exemplary embodiments, the first conducting material 910 and the second conducting material 920 are the same shape and size; while in other exemplary embodiments, one of the conducting materials 910, 920 is a different shape and/or size than the other conducting material 910, 920.

The first insulating material 930 and the second insulating material 940 are similar to one another in certain exemplary embodiments, but are different in other exemplary embodiments. According to one exemplary embodiment, the insulating materials 930, 940 are fabricated using paper; however, other suitable insulating materials, such as rubber, can be used. The first insulating material 930 is positioned adjacently above and in contact with the first conducting material 910. The second insulating material 940 is positioned adjacently below and in contact with the second conducting material 920. The first insulating material 930 and the second insulating material 940 provide a barrier to direct current flow only through a circuit 905, which is discussed in further detail below. In certain exemplary embodiments, the first insulating material 930 and the second insulating material 940 are the same shape and size; while in other exemplary embodiments, one of the insulating materials 930, 940 is a different shape and/or size than the other insulating material 930, 940. Additionally, in certain exemplary embodiments, the insulating materials 930, 940 is larger in size than its corresponding conducting material 910, 920. However, one or more of the insulating materials 930, 940 is either larger or smaller than its corresponding conducting material 910, 920 in alternative exemplary embodiments.

The Arbor Press 950 includes an upper plate 952 and abase plate 954. The upper plate 952 is positioned above the base plate 954 and is movable towards the base plate 954. In other exemplary embodiments, the base plate 954 is movable towards the upper plate 952. The first insulating material 930, the first conducting material 910, the cleaned leached PDC cutter 400, the second conducting material 920, and the second insulating material 940 are positioned between the upper plate 952 and the base plate 954 such that the second insulating material 940 is positioned adjacently above and in contact with the base plate 954. The upper plate 952 is moved towards the base plate 954 until the upper plate 952 applies a downward load 953 onto the cutting surface 412 of the cleaned leached PDC cutter 400. When the downward load 953 is applied, the first conducting material 910 is deformed and adapted to the rough and very stiff cutting surface 412, thereby minimizing contact resistance between the first conducting material 910 and the cutting surface 412 and greatly improving the capacitance measurement consistency. At this time, the base plate 954 also applies an upward load 955 onto the bottom surface 364 of the cleaned leached PDC cutter 400. When the upward load 955 is applied, the second conducting material 920 is deformed and adapted to the rough and very stiff bottom surface 364, thereby minimizing contact resistance between the second conducting material 920 and the bottom surface 364 and greatly improving the capacitance measurement consistency. In certain exemplary embodiments, the downward load 953 is equal to the upward load 955. The downward load 953 and the upward load 955 is about one hundred pounds; however, these loads 953, 955 range from about two pounds to about a critical load. The critical load is a load at which the cleaned leached PDC cutter 400 is damaged when applied thereto.

In one exemplary embodiment, the second insulating material 940 is positioned on the base plate 954, the second conducting material 920 is positioned on the second insulating material 940, the cleaned leached PDC cutter 400 is positioned on the second conducting material 920, the first conducting material 910 is positioned on the cleaned leached PDC cutter 400, and the first insulating material 930 is positioned on the first conducting material 910. The upper plate 952 is moved towards the first insulating material 930 until the downward load 953 is applied onto the cleaned leached PDC cutter 400. In an alternative exemplary embodiment, one or more components, such as the first insulating material 930 and the first conducting material 910, are coupled to the upper plate 952 prior to the upper plate 952 being moved towards the base plate 954. Although an Arbor Press 950 is used in the capacitance measuring system 900, other equipment capable of delivering equal and opposite loads to each of the cutting surface 412 and the bottom surface 364 of the cleaned leached PDC cutter 400 can be used in other exemplary embodiments.

One end of the first wire 830 is electrically coupled to the positive terminal 818 of the multi-meter 810, while the opposing end of the first wire 830 is electrically coupled to the first conducting material 910, which thereby becomes electrically coupled to the cutting surface 412 of the cleaned leached PDC cutter 400. In one exemplary embodiment, a clamp 990 is coupled to the opposing end of the first wire 830 which couples the first wire 830 to the first conducting material 910. One end of the second wire 840 is electrically coupled to the negative terminal 819 of the multi-meter 810, while the opposing end of the second wire 840 is electrically coupled to the second conducting material 920, which thereby becomes electrically coupled to the bottom surface 364 of the cleaned leached PDC cutter 400. In one exemplary embodiment, a clamp (not shown), similar to clamp 990, is coupled to the opposing end of the second wire 840, which couples the second wire 840 to the second conducting material 920. Hence, the circuit 905 is completed using the multi-meter 810, the first wire 830, the first conducting material 910, the cleaned leached PDC cutter 400, the second conducting material 920, and the second wire 840. The current is able to flow from the positive terminal 818 of the multi-meter 810 to the cutting surface 412 of the cleaned leached PDC cutter 400 through the first wire 830 and the first conducting material 910. The current then flows through the cleaned leached PDC cutter 400 to the bottom surface 364 of the cleaned leached PDC cutter 400. When the multi-meter 810 is turned on, a voltage differential exists between the cutting surface 412 and the bottom surface 364. The current then flows from the bottom surface 364 to the negative terminal 819 of the multi-meter 810 through the second conducting material 920 and the second wire 840. The first insulating material 930 and the second insulating material 940 prevent the current from flowing into the Arbor Press 950. The capacitance measurement of the cleaned leached PDC cutter 400 is determined when the value displayed on the display 816 reaches a peak value or remains constant for a period of time. The use, analyzing of the results, and other information regarding the capacitance measuring system 900 is described in U.S. patent application Ser. No. 13/401,188, entitled “Use of Capacitance to Analyze Polycrystalline Diamond” and filed on Feb. 21, 2012, which has been incorporated by reference herein.

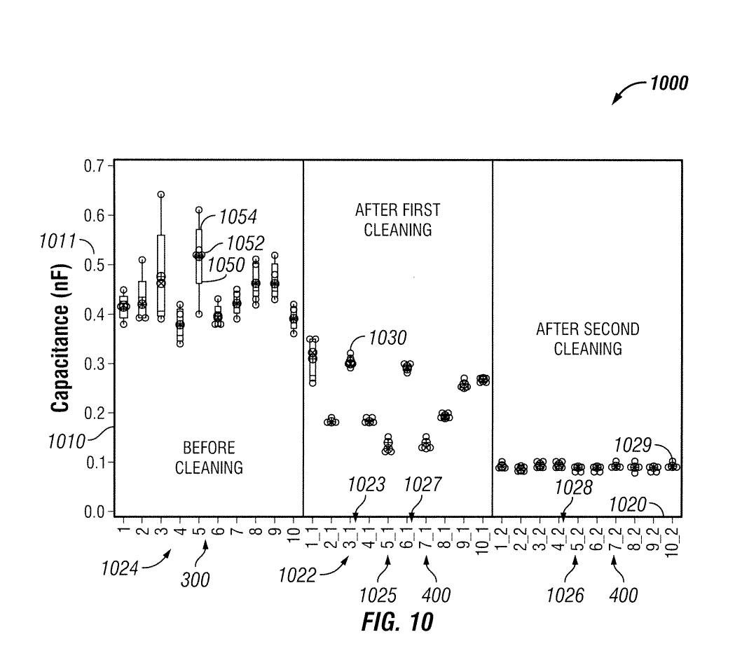

Referring back to FIG. 8, the by-product materials removal verification method 700 proceeds to step 750. At step 750, removal of at least a portion of the by-product materials from the cleaned leached PDC cutter and measuring at least one capacitance value for at least one of the cleaned leached PDC cutter is continued until the capacitance value is at a stable lower limit capacitance value. The removal of at least a portion of the by-product materials has been described with respect to step 730 and the measuring of the capacitance values has been described with respect to step 740. The stable lower limit capacitance value is the capacitance value of a cleaned leached PDC cutter at which the measured capacitance value does not further decrease upon further removal of by-product materials from the cleaned leached PDC cutter, i.e. further cleaning of the cleaned leached PDC cutter. The stable lower limit capacitance value is illustrated in FIG. 10.

FIG. 10 is a data scattering chart 1000 that shows the measured capacitance values 1011 for a plurality of leached and/or cleaned cutters 300, 400 at different cleaning cycles according to an exemplary embodiment. Referring to FIG. 10, the data scattering chart 1000 includes a cutter number axis 1020 and a capacitance axis 1010. The cutter number axis 1020 includes the number of the cutters 1022 tested along with a cleaning cycle number 1023. As shown, the first set of cutter numbers 1024 has not been cleaned of by-product materials 398 (FIG. 4), the second set of cutter numbers 1025 has been cleaned of by-product materials 398 (FIG. 4) through a first cleaning cycle 1027, and the third set of cutter numbers 1026 has been cleaned of by-product materials 398 (FIG. 4) through a second cleaning cycle 1028. The capacitance axis 1010 includes values for the measured capacitance 1011. A capacitance data point 1030 is obtained by measuring the capacitance of the leached and/or cleaned cutter 300, 400, or leached and/or cleaned component, using the capacitance measuring system 400 (FIG. 4), the capacitance measuring system 500 (FIG. 5), or a similar type system. Each capacitance data point 1030 for each cutter number 1022, with its respective cleaning cycle number 1023, is plotted on the data scattering chart 1000. Each cutter number 1022 has its capacitance measured a plurality of times. In some exemplary embodiments, five capacitance data points 1030 are obtained for each cutter number 1022, however, the number of measurements is greater or fewer in other exemplary embodiments. In some exemplary embodiments, a twenty-five percentile marking 1050, a fifty percentile marking 1052 (or average), and a seventy-five percentile marking 1054 is shown in the chart 1000 for each cutter number 1022. The area between the twenty-five percentile marking 1050 and the seventy-five percentile marking 1054 is shaded. The amount of data scattering is ascertained using this data scattering chart 1000 and can be one or more of a differential between the highest and lowest capacitance measurements 1011 for each cutter number 1022, a range between the twenty-five percentile marking 1050 and the seventy-five percentile marking 1054, or some similar observation made from the data scattering chart 1000.

According to FIG. 10, the first set of cutter numbers 1024, which has not yet been cleaned, shows a larger data scattering of capacitance values 1011 than when compared to the second set of cutter numbers 1025, which has been cleaned once for one hour using the by-products removal apparatus 500 (FIG. 5) or the by-products removal apparatus 600 (FIG. 6). Further, the second set of cutter numbers 1025, which has been cleaned once for one hour using the by-products removal apparatus 500 (FIG. 5) or the by-products removal apparatus 600 (FIG. 6), shows a larger data scattering of capacitance values 1011 than when compared to the third set of cutter numbers 1026, which has been cleaned a second time for another one hour using the by-products removal apparatus 500 (FIG. 5) or the by-products removal apparatus 600 (FIG. 6). The third set of cutter numbers 1026 exhibit a minimal, or negligible, amount of data scattering of capacitance values 1011. Thus, the capacitance values 1011 of the third set of cutter numbers 1026 is the stable lower limit capacitance value 1029 in this exemplary embodiment. However, it is possible, that if the third set of cutter numbers 1026 were to undergo an additional cleaning cycle, the capacitance values 1011 of the fourth set of cutter numbers (not shown) would be the stable lower limit capacitance value. When the stable lower limit capacitance value 1029 is reached, i.e. there is minimal to no data scattering of capacitance values 1011, the cleaned leached PDC cutters 400 are effectively cleaned and verified as such.

Referring back to FIG. 7, the by-product materials removal verification method 700 proceeds to step 760. At step 760, the by-product materials removal verification method 700 ends.

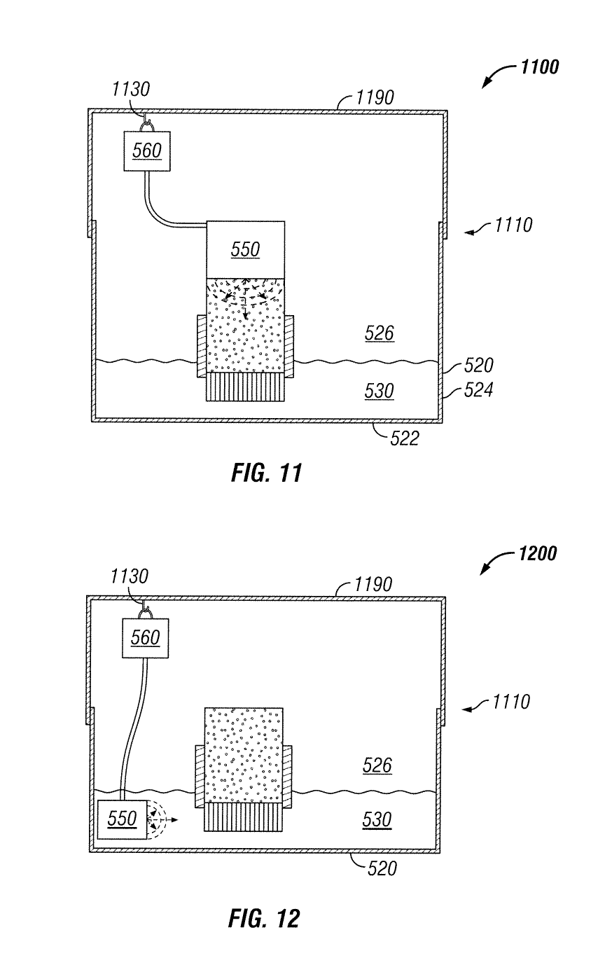

FIG. 11 is a cross-sectional view of a by-products removal apparatus 1100 in accordance with another exemplary embodiment. The by-products removal apparatus 1100 is similar to the by-products removal apparatus 500 (FIG. 5) except that the cavity 526 of the immersion tank 520 is covered by a lid 1190 in the by-products removal apparatus 1100. In certain exemplary embodiments, the lid 1190 provides a seal to the cavity 526, thereby allowing the cavity 526 to be pressurized and the cleaning fluid 530 to be heated at higher temperatures, such as above 100° C. These higher temperatures increase the cleaning rate of the by-products materials 398 (FIG. 3). A gasket (not shown) positioned between the lid 1190 and the immersion tank 520 can be used to facilitate providing the seal. The sealed lid 1190 and the immersion tank 520 collectively form the pressurizable vessel 1110. In the exemplary embodiments that use the lid 1190, the power source 560 can be coupled to the lid 1190 via a clamp 1130, can be positioned outside the pressurizable vessel 1110 as long as the pressurized vessel 1110 provides a port (not shown) to electrically couple the power source 560 to the transducer 550, or can be integrated with the transducer 550. The other exemplary embodiments and/or modifications as described with respect to FIG. 5 above are applicable to the present exemplary embodiment.

FIG. 12 is a cross-sectional view of a by-products removal apparatus 1200 in accordance with another exemplary embodiment. The by-products removal apparatus 1200 is similar to the by-products removal apparatus 600 (FIG. 6) except that the cavity 526 of the immersion tank 520 is covered by a lid 1190 in the by-products removal apparatus 1200. In certain exemplary embodiments, the lid 1190 provides a seal to the cavity 526, thereby allowing the cavity 526 to be pressurized and the cleaning fluid 530 to be heated at higher temperatures, such as above 100° C. These higher temperatures increase the cleaning rate of the by-products materials 398 (FIG. 3). A gasket (not shown) positioned between the lid 1190 and the immersion tank 520 can be used to facilitate providing the seal. The sealed lid 1190 and the immersion tank 520 collectively form the pressurizable vessel 1110. In the exemplary embodiments that use the lid 1190, the power source 560 can be coupled to the lid 1190 via a clamp 1130, can be positioned outside the pressurizable vessel 1110 as long as the pressurized vessel 1110 provides a port (not shown) to electrically couple the power source 560 to the transducer 550, or can be integrated with the transducer 550. The other exemplary embodiments and/or modifications as described with respect to FIG. 5 and above are applicable to the present exemplary embodiment.

A cleaned leached PDC cutter, which is substantially free of by-product materials, or catalyst metal salts, has a superior wear abrasion resistance with an increased thermal stability. Thus, the apparatus and methods disclosed herein minimizes the detrimental effects of the leaching reaction by-product materials.

Although each exemplary embodiment has been described in detail, it is to be construed that any features and modifications that are applicable to one embodiment are also applicable to the other embodiments. Furthermore, although the invention has been described with reference to specific embodiments, these descriptions are not meant to be construed in a limiting sense. Various modifications of the disclosed embodiments, as well as alternative embodiments of the invention will become apparent to persons of ordinary skill in the art upon reference to the description of the exemplary embodiments. It should be appreciated by those of ordinary skill in the art that the conception and the specific embodiments disclosed may be readily utilized as a basis for modifying or designing other structures or methods for carrying out the same purposes of the invention. It should also be realized by those of ordinary skill in the art that such equivalent constructions do not depart from the spirit and scope of the invention as set forth in the appended claims. It is therefore, contemplated that the claims will cover any such modifications or embodiments that fall within the scope of the invention.

What is claimed is:

1. A by-products removal apparatus, comprising:
a tank comprising a base and a wall extending substantially around and away from the perimeter of the base forming a cavity therein;
a cleaning fluid placed within the cavity; and
a component comprising a polycrystalline structure, the polycrystalline structure comprising a leached layer and an unleached layer positioned adjacent to the leached layer, the leached layer having a lesser concentration of a catalyst material than the unleached layer, the leached layer comprising a plurality of by-product materials deposited therein;
wherein at least a portion of the leached layer is immersed within the cleaning fluid, and
wherein at least a portion of the by-products materials is soluble into the cleaning fluid.

2. The by-products removal apparatus of claim 1, further comprising a transducer acoustically coupled to the component, the transducer emitting vibrations into the component.

3. The by-products removal apparatus of claim 2, wherein the transducer is coupled to a surface of the component.

4. The by-products removal apparatus of claim 2, wherein the transducer is coupled to the tank.

5. The by-products removal apparatus of claim 2, wherein the transducer is immersed into the cleaning fluid.

6. The by-products removal apparatus of claim 1, wherein the component comprises a cutter, the cutter comprising a substrate having a top surface and a bottom surface and a cutting table coupled to the top surface of the substrate, wherein the cutting table comprises the polycrystalline structure.

7. The by-products removal apparatus of claim 6, further comprising a covering surrounding at least a portion of the circumferential surface of the cutter, the portion of the circumferential surface extending from at least the top surface towards the bottom surface.

8. The by-products removal apparatus of claim 1, wherein the cleaning fluid comprises at least one of a de-ionized water and a de-ionized water solution.

9. The by-products removal apparatus of claim 1, further comprising a lid coupled to the tank and enclosing the cavity.

10. A cleaned leached cutter, comprising:
a substrate; and
a cutting table coupled to a surface of the substrate, the cutting table comprising a polycrystalline structure, the polycrystalline structure, comprising:
an unleached layer positioned adjacent to the substrate and comprising a plurality of catalyst material deposited therein; and
a leached layer positioned adjacent to the unleached layer and comprising one or more by-product materials deposited therein,
wherein at least a portion of the by-product materials have been removed from the leached layer, and
wherein the by-product materials are formed from a leaching process used to remove at least a portion of the catalyst material from the leached layer.

11. The cleaned leached cutter of claim 10, wherein the surface of the substrate is non-planar.

12. The cleaned leached cutter of claim 10, wherein the by-product material is a salt of the catalyst material and is soluble within de-ionized water.

13. A method for removing one or more by-product materials from a leached component having at least a leached layer, the leached layer comprising a plurality of by-product materials deposited therein, the method comprising:
obtaining a tank forming a cavity therein;
placing a cleaning fluid within at least a portion of the cavity;
placing at least a portion of leached layer of a leached component within the cleaning fluid, the leached component comprising a polycrystalline structure, the polycrystalline structure comprising at least a leached layer, the leached layer comprising a plurality of by-product materials deposited therein, the by-product materials being formed during a leaching process that removes at least a portion of a catalyst material from the leached layer; and
removing at least a portion of the by-product materials from the leached layer,
wherein the by-product materials is soluble within the cleaning fluid.

14. The method of claim 13, further comprising acoustically coupling a transducer to the component, wherein the transducer emits vibrations into the component.

15. The method of claim 14, wherein the transducer is immersed into the cleaning fluid.

16. The method of claim 13, wherein the component comprises a cutter, the cutter comprising a substrate having a top surface and a bottom surface and a cutting table coupled to the top surface of the substrate, wherein the cutting table comprises the polycrystalline structure.

17. The method of claim 16, further comprising placing a covering around at least a portion of a circumferential surface of the cutter, the portion of the circumferential surface extending from at least the top surface towards the bottom surface, and wherein a portion of the covering is immersed into the cleaning fluid.

18. The method of claim 13, wherein the cleaning fluid comprises de-ionized water.

19. The method of claim 13, further comprising heating the cleaning fluid.

20. A method for determining the effectiveness of removing one or more by-product materials from within a leached layer of a polycrystalline structure, the method comprising:
obtaining one or more leached components, each leached component comprising a polycrystalline structure, the polycrystalline structure comprising at least a leached layer, the leached layer comprising one or more by-product materials deposited therein, the by-product materials being formed during a leaching process that removes at least a portion of a catalyst material from the leached layer;
removing at least a portion of the by-product materials from the leached layer thereby forming a cleaned leached component;
measuring at least one capacitance value for each of the cleaned leached component;
continuing the removing of at least a portion of the by-product materials from the leached layer and the measuring of at least one capacitance value for each of the cleaned leached component until the capacitance values for each of the cleaned leached components are at a stable lower limit capacitance value.

21. The method of claim 20, further comprising measuring at least one capacitance value for each of the leached components.

22. The method of claim 20, wherein removing at least a portion of the by-product materials comprises:
inserting at least a portion of the leached layer into a cleaning fluid; and
dissolving at least a portion of the by-product materials into the cleaning fluid,
wherein the cleaning fluid comprises de-ionized water.

23. The method of claim 22, wherein removing at least a portion of the by-product materials further comprises heating the cleaning fluid.
